(19) United States
(12) Patent Application Publication
(10) Pub. No.: US 2026/0352210 A1
(43) Pub. Date: Nov. 5, 2026

(54) COMPACT MULTIPLEXER WITH MULTI-THRESHOLD FERROELECTRIC FETS

(71) Applicants: University of Notre Dame du Lac, South Bend, IN (US); NDSU Research Foundation, Fargo, ND (US)

(72) Inventors: Kai Ni, South Bend, IN (US); Sanwar Ahmed Ovy, Fargo, ND (US); Sumitha George, Fargo, ND (US); Md Ashraful Islam Romel, Fargo, ND (US)

(73) Assignee: NDSU Research Foundation, Fargo, ND (US)

(21) Appl. No.: 19/665,723

(22) Filed: May 1, 2026

Related U.S. Application Data
(60) Provisional application No. 63/798,178, filed on May 1, 2025.

(51) Int. Cl. H03K 17/693; G11C 11/22; H10D 30/69

(52) U.S. Cl. CPC H03K 17/693; G11C 11/223; G11C 11/2273; G11C 11/2275; H10D 30/701

(57) ABSTRACT

According to an embodiment, a multiplexer circuit comprises a first block of variable-threshold transistors coupled to a first select line, the transistors in the first block arranged in an ascending order of threshold voltage. The multiplexer circuit also comprises a second block of variable-threshold transistors coupled to a second select line, the transistors in the second block arranged in a descending order of threshold voltage, each transistor in the second block connected in series with a respective transistor in the first block to form a plurality of input-to-output paths. Applying a respective voltage level to each of the first and second select lines activates a single input-to-output path through the first and second blocks.

### CROSS-REFERENCE TO RELATED APPLICATIONS

The present disclosure claims benefit of US Provisional Application No. 63/798,178, titled “COMPACT MULTIPLEXER WITH MULTITHRESHOLD FERROELECTRIC FETS” and filed May 1, 2025, which is hereby incorporated by reference in its entirety.

### GOVERNMENT LICENSE RIGHTS

This invention was made with government support under grants 2246149 and ECCS2346953 awarded by the National Science Foundation (NSF). The government has certain rights in the invention.

### TECHNICAL FIELD

The present disclosure relates to multiplexer circuits for integrated circuits, and more particularly to multiplexer architectures that use transistors having programmable or variable threshold voltages.

### BACKGROUND

Multiplexers are combinational circuits that select one of multiple input signals and route the selected input to a single output under the control of selection signals. Multiplexers are used in a variety of integrated circuit applications, including processors, network switches, digital signal processors, application-specific integrated circuits (ASICs), and field-programmable gate arrays (FPGAs).

### BRIEF DESCRIPTION OF THE DRAWINGS

Certain features of the subject technology are set forth in the appended claims. However, for the purpose of explanation, several embodiments of the subject technology are set forth in the following figures, where like reference numerals refer to the same or similar features in the various figures.

FIG. 1A is a cross-sectional view of a ferroelectric field-effect transistor (FeFET) device structure, according to one or more embodiments.

FIG. 1B is an equivalent circuit model of the FeFET device of FIG. 1A.

FIG. 2 is a graph illustrating drain current versus gate-source voltage characteristics of a FeFET programmed to multiple threshold voltage states, according to one or more embodiments.

FIG. 3 is a series of circuit block diagrams illustrating unique input-to-output path selection in a two-block multiplexer arrangement with four inputs and four threshold voltage levels, according to one or more embodiments.

FIG. 4 is a circuit schematic of an example 4:1 multiplexer, according to one or more embodiments.

FIG. 5 is a series of circuit schematics of example 8:1 multiplexers, according to one or more embodiments.

FIG. 6 is a timing diagram illustrating a transient response of the proposed 4:1 multiplexer of FIG. 4.

FIG. 7 is a timing diagram illustrating a transient response of the proposed 8:1 multiplexer of FIG. 5.

FIG. 8 is a flowchart illustrating a method of operating a multiplexer having variable-threshold transistors, according to one or more embodiments.

FIG. 9 is a flowchart illustrating a method of manufacturing a multiplexer, according to one or more embodiments.

FIG. 10 is a block diagram illustrating a computing device, according to one or more embodiments.

### DETAILED DESCRIPTION

Multiplexers (MUX) are among the most frequently used components in processors, network switches, and digital signal processors. In application-specific integrated circuits (ASICs), multiplexers are employed in routing structures in networks on chip and in non-trivial logic implementations. In field-programmable gate arrays (FPGAs), multiplexers form a significant portion of look-up tables (LUTs). For example, multiplexers may account for over 25% of the area of an FPGA design. Accordingly, multiplexer efficiency directly impacts integrated circuit design in terms of area, power, and latency.

Among multiplexer implementation approaches, pass-transistor (PT) based designs are used in several applications because of their implementation simplicity, low area, low power consumption, and minimal transistor count. However, pass-transistor multiplexer trees have inherent scaling limitations. As multiplexer input size increases, the number of transistors grows and additional intermediate stages are required in the multiplexer tree. The increased intermediate stages may also necessitate level restorers. For example, an 8:1 multiplexer conventionally requires three stages and fourteen transistors, and a 16:1 multiplexer conventionally requires four stages and thirty transistors.

The present disclosure addresses these scaling limitations by utilizing the multi-level threshold voltages of variable-threshold transistors for a multiplexer circuit design. In some embodiments, the variable-threshold transistors are ferroelectric field-effect transistors (FeFETs), which can be programmed to multiple threshold voltage states through partial polarization switching of a ferroelectric layer. In other embodiments, the variable-threshold transistors may be other transistor technologies in which individual devices can be configured to have different threshold voltages. Although the disclosed architectures are applicable to any multi-threshold transistor technology, FeFETs offer additional flexibility in tuning transistor threshold voltages, selecting operating voltage ranges, and providing enhanced control over noise margins through their voltage-controlled programmable threshold characteristic.

Some embodiments of the disclosed architectures include transistors arranged inside a block based on their threshold voltage. In a first block, transistors are arranged in an ascending order of threshold voltage, and in a second block connected in series with the first block, transistors are arranged in a descending order of threshold voltage. This arrangement enables efficient selection of multiplexer inputs using multi-level voltage signals on shared select lines rather than binary high/low signals, achieving a greater-than-2:1 input reduction per stage. As a result, the disclosed architecture reduces the total number of transistors and the number of intermediate stages compared to a traditional pass-transistor multiplexer.

The disclosed designs are scalable with multiplexer size. As the multiplexer input count and the number of available threshold voltage levels increase, the savings in transistors and stages grow correspondingly. Using four threshold voltage levels, the disclosed architecture saves two transistors (14.29%) on an 8:1 multiplexer and reduces the number of stages from three to two; for a 16:1 multiplexer, the architecture saves six transistors (20%) and reduces the number of stages from four to two; and so on.

Additional details, tests, and test results may be found in Ovy, Sanwar Ahmed, et al., “Compact Multiplexer Design with Multi-threshold Ferroelectric FETs,” 2024 IEEE Computer Society Annual Symposium on VLSI (ISVLSI), which is hereby incorporated by reference in its entirety.

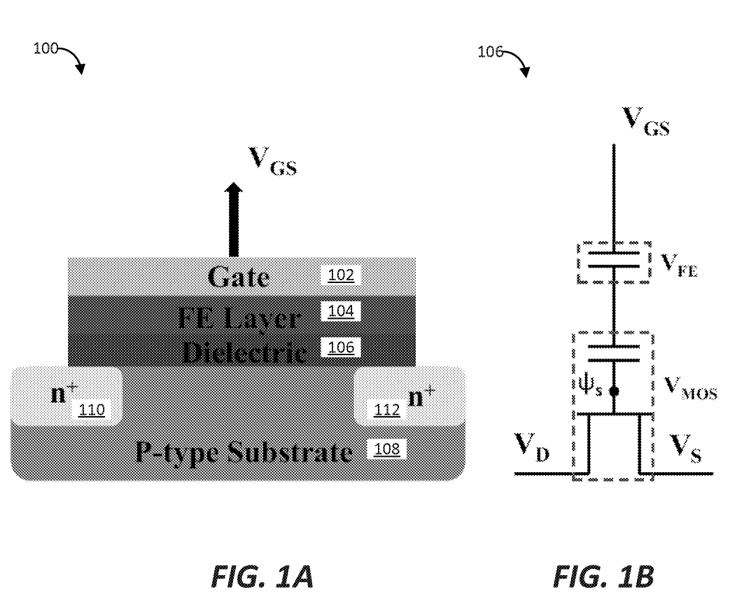

Referring now to the drawings, wherein like numerals refer to the same or similar features in the various figures, FIG. 1A is a cross-sectional view of a FeFET device 100, according to one or more embodiments. Not all of the depicted components may be used in all embodiments, and one or more embodiments may include additional, fewer, or different components than those shown in the figure. Variations in the arrangement and type of components may be made without departing from the spirit or scope of the claims as set forth herein.

The device 100 includes a gate stack including a gate 102 and a ferroelectric layer 104. The ferroelectric layer 104 may include a ferroelectric hafnium oxide material, such as Tungsten (W) doped amorphous In₂O₃ (IWO) channel on hafnium zirconium oxide Hf_{0.5}Zr_{0.5}O₂ (HZO), silicon-doped hafnium oxide (HSO), and/or other doped hafnium oxide compositions that exhibit ferroelectric behavior.

A dielectric 106 may be disposed between the ferroelectric layer 104 and a p-type substrate 108. The p-type substrate 108 may include an n+ source region 110 and/or an n+ drain region 112 on opposing sides of the substrate 108.

Ferroelectric polarization of the ferroelectric layer 104 may store information that can be altered by the application of an external electric field at the gate 102 and that persists after the removal of the external field, making the device nonvolatile. Application of a positive write pulse to the gate 102 sets the polarization pointing toward the channel, which attracts channel electron concentration and sets the device to a low threshold voltage state. Application of a negative write pulse to the gate 102 sets the polarization pointing toward the gate metal, which depletes channel electron concentration and sets the device to a high threshold voltage state. Write pulses of different amplitudes or pulse widths can access intermediate polarization states through partial polarization switching in a multi-domain ferroelectric thin film, enabling the realization of nonvolatile multi-bit storage.

The multiplexer architectures described herein are applicable to any transistor technology in which individual transistors can be configured to have different threshold voltages.

Referring now to FIG. 1B, an equivalent circuit model of the FeFET device of FIG. 1A is shown. The equivalent circuit represents the FeFET as a ferroelectric capacitor in series with an internal gate node of a conventional MOSFET. The voltage across the ferroelectric capacitor is denoted V_{FE}, and the voltage across the internal MOSFET gate oxide is denoted V_{MOS}, such that V_{GS} = V_{FE} + V_{MOS}. The drain voltage V_{D} and source voltage V_{S} are also indicated.

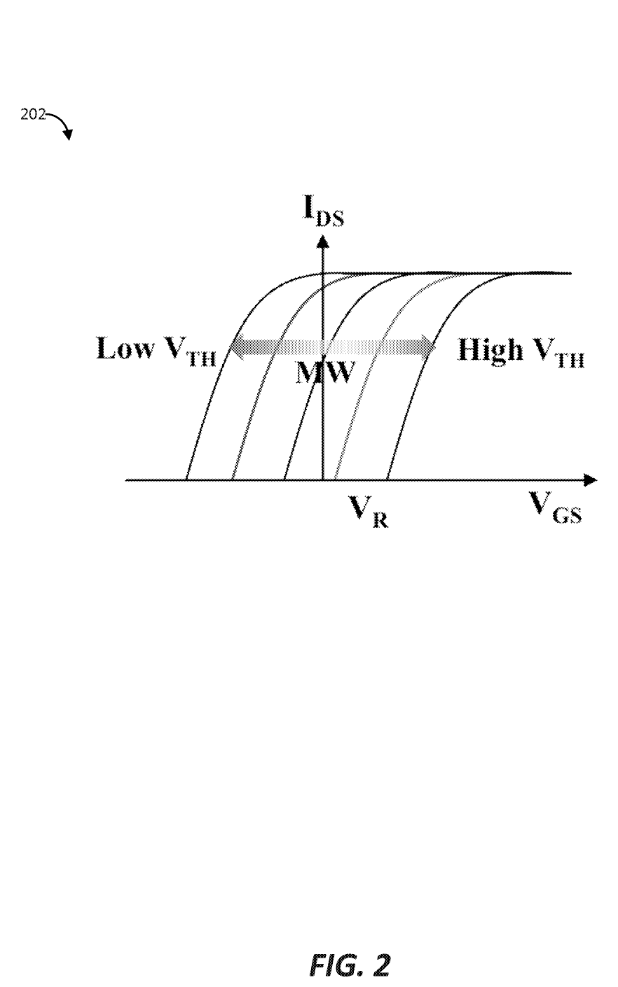

Referring now to FIG. 2, a graph 202 illustrates drain current (I_{DS}) versus gate-source voltage (V_{GS}) characteristics of a FeFET programmed to multiple threshold voltage states. The horizontal axis represents V_{GS} and the vertical axis represents I_{DS}. The graph 202 shows curves corresponding to different polarization states of the ferroelectric layer 104, ranging from a low V_{TH} state to a high V_{TH} state. The separation between the low V_{TH} and high V_{TH} curves defines a memory window (MW), which represents the range of threshold voltages accessible through partial polarization switching. Within this memory window, intermediate threshold voltage states (e.g., V_{TH1}, V_{TH2}, V_{TH3}, V_{TH4}) can be programmed by applying write pulses of different amplitudes or pulse widths. Also shown in the graph 202 is a representative read voltage V_{R}, which falls between adjacent threshold voltage states and is used during multiplexer operation to selectively activate transistors based on their programmed threshold voltage.

The multi-threshold voltage programmability illustrated in the graph 202 is the basis for the multiplexer architectures described herein. In a conventional pass-transistor multiplexer, all transistors in the multiplexer tree share a single threshold voltage, and binary select signals (logic high or logic low) control which transistors are on or off at each stage. By contrast, in the disclosed multiplexer architecture, transistors within each block are programmed to different threshold voltage states (e.g., V_{TH1}, V_{TH2}, V_{TH3}, V_{TH4}), and multi-level read voltages on the select lines selectively turn on subsets of those transistors based on the relationship between the applied read voltage and the individual threshold voltages.

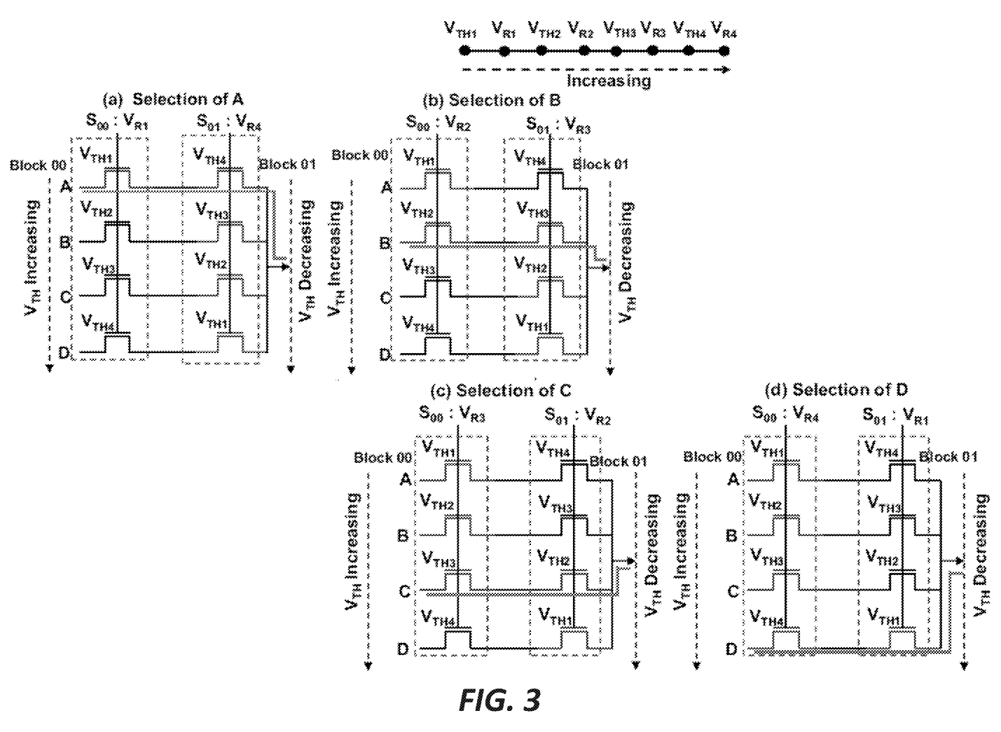

For a multiplexer with N distinct threshold voltages, N corresponding discrete read voltages V_{R1} through V_{RN} are defined such that V_{R1}is greater than V_{TH1} and less than V_{TH2}, V_{R2} is greater than V_{TH2} and less than V_{TH3}, and so on, with V_{RN} being greater than V_{THN}. More generally, the threshold voltages and read voltages satisfy the ordering: 0 < V_{TH1} < V_{R1} < V_{TH2} < V_{R2} < ... < V_{THN} < V_{RN}. When a read voltage V_{Rk} is applied to a select line of a block, all transistors in that block having a threshold voltage of V_{THk} or lower are turned on, while transistors having a threshold voltage of V_{TH(k+1)} or higher remain off. This selective activation based on the interleaving of threshold voltages and read voltages enables the input selection mechanism described with reference to FIG. 3.

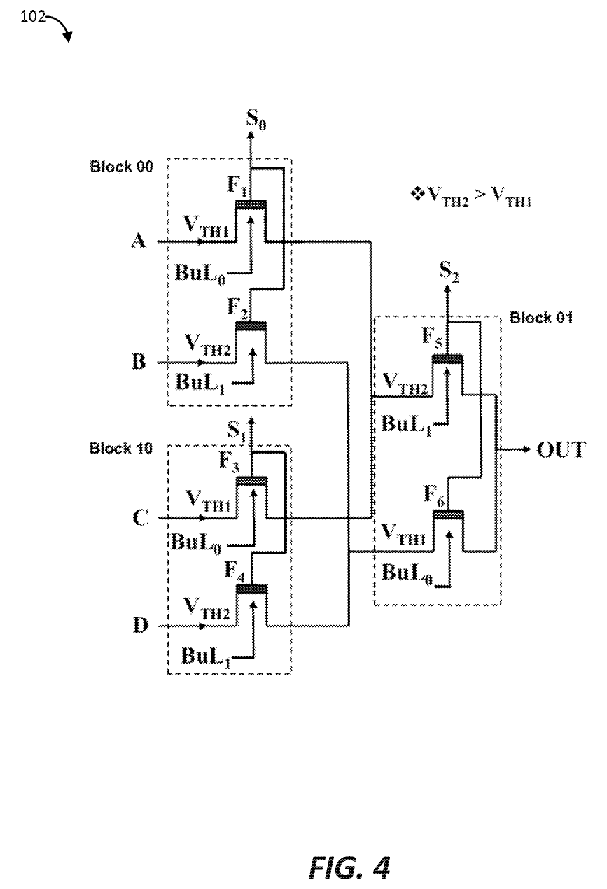

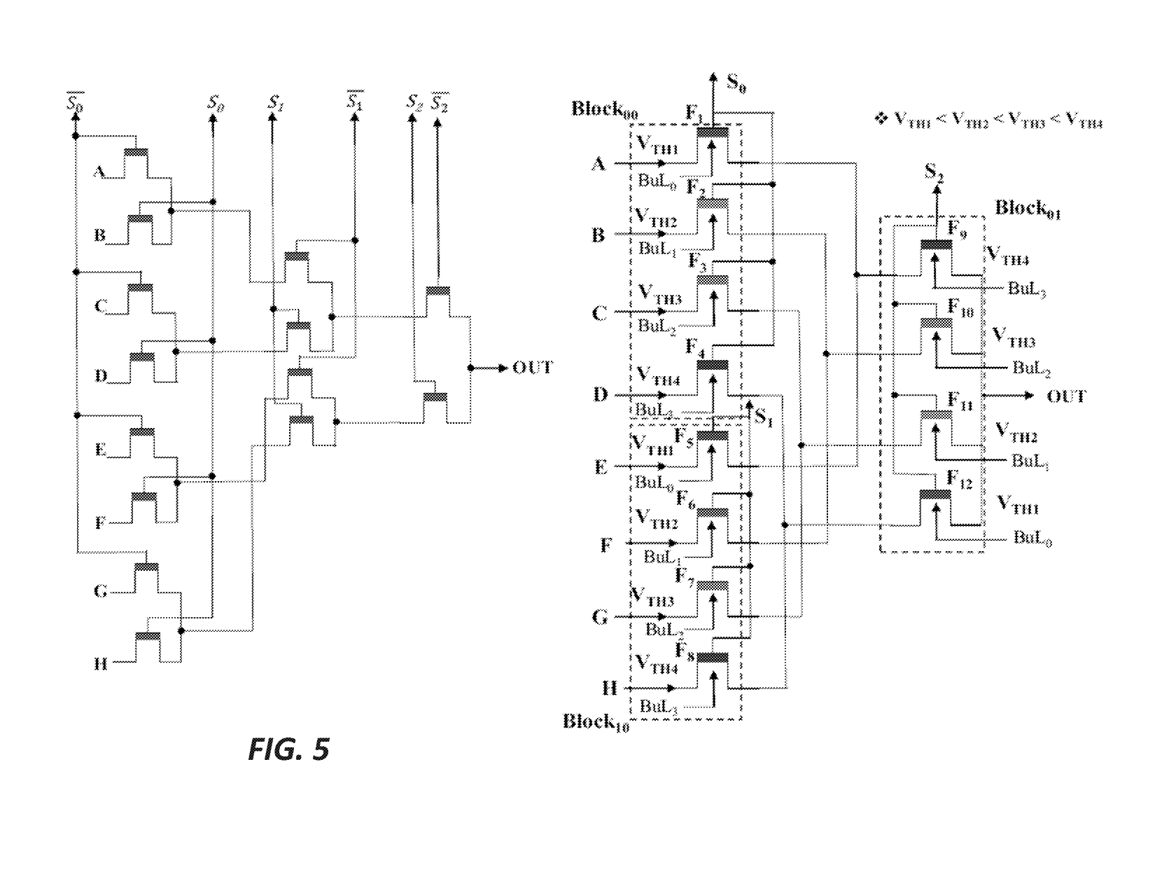

Although FIG. 2 depicts five threshold voltage states, the number of distinct threshold voltage states is not limited to five. In some embodiments, two threshold voltage states are used, as described with reference to the 4:1 multiplexer of FIG. 4. In some embodiments, four threshold voltage states are used, as described with reference to the 8:1 multiplexer of FIG. 5. In further embodiments, a greater number of threshold voltage states (e.g., eight or sixteen) may be used to construct larger multiplexer configurations with correspondingly greater transistor and stage savings.

Referring now to FIG. 3, a series of circuit block diagrams illustrates the input selection mechanism of a base unit of an example multiplexer architecture using a two-block arrangement with four inputs (A, B, C, D) and four threshold voltage levels (V_{TH1}, V_{TH2}, V_{TH3}, V_{TH4}). FIG. 3 includes four panels labeled A through D, each depicting the conduction path activated for a respective input.

The multiplexer arrangement of FIG. 3 includes a first block (Block 00) and a second block (Block 01). The first block (Block 00) includes four variable-threshold transistors coupled to a first select line S₀₀. The transistors in the first block are arranged in a first (e.g., ascending) order of threshold voltage from top to bottom: V_{TH1}, V_{TH2}, V_{TH3}, V_{TH4}. Each transistor in the first block is coupled to a respective input terminal (A, B, C, D). The second block (Block 01) includes four variable-threshold transistors coupled to a second select line S₀₁. The transistors in the second block are arranged in a second (e.g., descending) order of threshold voltage from top to bottom: V_{TH4}, V_{TH3}, V_{TH2}, V_{TH1}. Each transistor in the second block is connected in series with a respective transistor in the first block. The series-connected pairs form four input-to-output paths, each coupling a respective input terminal to an output terminal through one transistor of the first block and one transistor of the second block.

The select lines S₀₀ and S₀₁ carry multi-level voltage signals rather than binary high/low signals. As described with reference to FIG. 2, discrete read voltages V_{R1}, V_{R2}, V_{R3}, V_{R4} are interleaved with the threshold voltages such that 0 < V_{TH1} < V_{R1} < V_{TH2} < V_{R2} < V_{TH3} < V_{R3} < V_{TH4} < V_{R4}. The selection of a particular input is achieved by applying a specific pair of read voltages to S₀₀ and S₀₁.

Panel A illustrates the selection of input A. The first select line S₀₀ is biased at V_{R1}, which turns on only the transistor with V_{TH1} (the transistor connected to input A) in the first block, because V_{R1} exceeds V_{TH1} but falls below V_{TH2}, V_{TH3}, and V_{TH4}. Input A passes through this transistor to the corresponding transistor in the second block, which has threshold voltage V_{TH4}. The second select line S₀₁ is biased at V_{R4}, which exceeds all four threshold voltages and turns on all transistors in the second block. Although all transistors in the second block are turned on, only the path from input A carries a signal from the first block.

Panel B illustrates the selection of input B. The first select line S₀₀ is biased at V_{R2}, turning on the transistors with V_{TH1} and V_{TH2} in the first block (the transistors connected to inputs A and B). Inputs A and B pass to the second block. The second select line S₀₁ is biased at V_{R3}, turning on the three transistors in the second block (V_{TH3}, V_{TH2}, and V_{TH1}). In the second block, input A arrives at the transistor with V_{TH4}, which remains off because V_{R3} < V_{TH4}. Input B arrives at the transistor with V_{TH3}, which is turned on. Accordingly, only input B passes through the second block to the output.

Panel C illustrates the selection of input C. The first select line S₀₀ is biased at V_{R3}. Inputs A, B, and C pass to the second block. The second select line S₀₁ is biased at V_{R2}, turning on two transistors in the second block (V_{TH2}, V_{TH1}). Input C arrives at the second-block transistor with V_{TH2}, which is on, while inputs A and B arrive at second-block transistors with V_{TH4} and V_{TH3}, respectively, both of which are off. Accordingly, only input C passes through the second block to the output.

Panel D illustrates the selection of input D. The first select line S₀₀ is biased at V_{R4}. All inputs pass to the second block. The second select line S₀₁ is biased at V_{R1}, turning on only the transistor with V_{TH1} in the second block. Input D, which connects through the V_{TH4} transistor in the first block to the V_{TH1} transistor in the second block, is the only input that reaches the output.

Referring now to FIG. 4, a circuit schematic of an example 4:1 multiplexer is shown, according to one or more embodiments. The 4:1 multiplexer uses two threshold voltage levels (V_{TH1}, V_{TH2}) and includes six transistors (F₁ through F₆) arranged across two stages.

The first stage includes two blocks: Block 00 and Block 10. Block 00 is a block of variable-threshold transistors coupled to a first select line S₀. Block 00 includes transistors F₁ and F₂, with F₁ having threshold voltage V_{TH1} and F₂ having threshold voltage V_{TH2}. The transistors in Block 00 are arranged in ascending order of threshold voltage. Transistor F₁ is coupled to input A, and transistor F₂ is coupled to input B. Block 10 is a block of variable-threshold transistors coupled to a select line S₁. Block 10 includes transistors F₃ and F₄, with F₃ having threshold voltage V_{TH1} and F₄ having threshold voltage V_{TH2}. The transistors in Block 10 are also arranged in ascending order of threshold voltage. Transistor F₃ is coupled to input C, and transistor F₄ is coupled to input D.

The second stage includes one block: Block 01. Block 01 is a block of variable-threshold transistors coupled to a select line S₂. Block 01 includes transistors F₅ and F₆, with F₅ having threshold voltage V_{TH2} and F₆ having threshold voltage V_{TH1}. The transistors in Block 01 are arranged in descending order of threshold voltage. Block 01 receives intermediate outputs from Block 00 and Block 10. Specifically, the output of transistor F₁ or F₃ connects to transistor F₅, and the output of transistor F₂ or F₄ connects to transistor F₆. The output terminal of the multiplexer is formed by shorting the outgoing nodes from Block 01.

The threshold voltages and read voltages follow the ordering 0 < V_{TH1} < V_{R1} < V_{TH2} < V_{R2}. To select input A, select lines are biased as S₀ = V_{R1}, S₁ = 0, S₂ = V_{R2}. To select input B, the select lines are biased as S₀ = V_{R2}, S₁ = 0, S₂ = V_{R1}. To select input C, the select lines are biased as S₀ = 0, S₁ = V_{R1}, S₂ = V_{R2}. To select input D, the select lines are biased as S₀ = 0, S₁ = V_{R2}, S₂ = V_{R1}.

In some embodiments, each of the transistors F₁ through F₆ is a FeFET. In such embodiments, body bias lines BuL₀ and BuL₁ are coupled to respective transistors to support selective programming of threshold voltages, as discussed below with reference to FIG. 4. Body bias line BuL₀ is coupled to transistors programmed to V_{TH1} (F₁, F₃, F₆), and body bias line BuL₁ is coupled to transistors programmed to V_{TH2} (F₂, F₄, F₅). During a write operation, the body bias lines provide inhibit biasing to non-targeted transistors to prevent unintended reprogramming of their threshold voltage states.

Referring now to FIG. 5, two circuit schematics are shown side by side for comparison. Panel A depicts an 8:1 NMOS multiplexer, and Panel B depicts the 8:1 multiplexer using four threshold voltage levels according to one or more embodiments.

The 8:1 multiplexer of panel A includes three stages of pass transistors, with each stage providing a 2:1 input reduction. The first stage includes four pairs of transistors controlled by a first set of select lines (S₀, S'₀), selecting among eight inputs (A through H) to produce four intermediate outputs. The second stage includes two pairs of transistors controlled by a second set of select lines (S₁, S'₁), reducing the four intermediate outputs to two. The third stage includes one pair of transistors controlled by a third set of select lines ( S₂, S’₂) producing the final output. The conventional design uses fourteen transistors across three stages and includes six select lines (three select lines and three complementary select lines).

The 8:1 multiplexer of panel B, according to one or more embodiments of the present disclosure, includes two stages of variable-threshold transistors using four threshold voltage levels (V_{TH1}, V_{TH2}, V_{TH3}, V_{TH4}). The first stage includes two blocks: Block 00 and Block 10. Block 00 is coupled to a select line S₀ and includes four transistors (F₁, F₂, F₃, F₄) arranged in a first (e.g., ascending) order of threshold voltage: F₁ at V_{TH1}, F₂ at V_{TH2}, F₃ at V_{TH3}, and F₄ at V_{TH4}. Transistors F₁ through F₄ are coupled to input terminals A, B, C, and D, respectively. Block 10 is coupled to a select line S₁ and includes four transistors (F₅, F₆, F₇, F₈) also arranged in the first order of threshold voltage: F₅ at V_{TH1}, F₆ at V_{TH2}, F₇ at V_{TH3}, and F₈ at V_{TH4}. Transistors F₅ through F₈ are coupled to input terminals E, F, G, and H, respectively.

The second stage includes one block: Block 01. Block 01 is coupled to a third select line S₂ and includes four transistors (F₉, F₁₀, F₁₁, F₁₂) arranged in descending order of threshold voltage: F₉ at V_{TH4}, F₁₀ at V_{TH3}, F₁₁ at V_{TH2}, and F₁₂ at V_{TH1}. Block 01 receives intermediate outputs from Block 00 and Block 10. The outputs of Block 00 (from F₁ through F₄) connect to transistors F₉ through F₁₂, and the outputs of Block 10 (from F₅ through F₈) also connect to transistors F₉ through F₁₂. The output terminal of the multiplexer is formed by shorting the outgoing nodes from Block 01.

The threshold voltages and read voltages for the 8:1 multiplexer follow the ordering 0 < V_{TH1} < V_{R1} < V_{TH2} < V_{R2} < V_{TH3} < V_{R3} < V_{TH4} < V_{R4}. To select input A, the biasing is (S₀, S₁, S₂) = (V_{R1}, 0, V_{R4}). The voltage V_{R1} on S₀ turns on only F₁ (V_{TH1}) in Block 00. The voltage V_{R4} on S₂ turns on all transistors in Block 01. Block 10 is inactive because S1 = 0. Accordingly, input A passes through F₁ and F₉ to the output. To select input B, the biasing is (S₀, S₁, S₂) = (V_{R2}, 0, V_{R3}). The voltage V_{R2} on S₀ turns on F₁ (V_{TH1}) and F₂ (V_{TH2}). In Block 01, V_{R3} turns on F₁₀ (V_{TH3}), F₁₁ (V_{TH2}), and F₁₂ (V_{TH1}). Input B, arriving from F₂, connects to F₁₀ in the second block, which is on, while input A, arriving from F₁, connects to F₉, which is off. Accordingly, only input B reaches the output.

The selection of inputs C and D follow a similar pattern with biasing (V_{R3}, 0, V_{R2}) and (V_{R4}, 0, V_{R1}), respectively. To select inputs E through H, the first select line S₀ is set to 0 (deactivating Block 00), and the second select line S₁ is activated with the appropriate read voltage: (0, V_{R1}, V_{R4}) for input E, (0, V_{R2}, V_{R3}) for input F, (0, V_{R3}, V_{R2}) for input G, and (0, V_{R4}, V_{R1}) for input H.

The 8:1 multiplexer in panel B uses twelve transistors across two stages, compared to fourteen transistors across three stages in the conventional design of panel A. This represents a reduction of two transistors (14.29%) and a reduction from three stages to two stages. The reduction in stage count decreases the series resistance of the signal path and reduces propagation delay. The proposed design also requires only three select lines (S₀, S₁, S₂) without complementary select lines, compared to the six select lines (three select lines and three complements) required by the conventional design.

In some embodiments, body bias lines BuL₀, BuL₁, BuL₂, and BuL₃ are coupled to the transistors in the 8:1 multiplexer to support selective programming of threshold voltages when the transistors are FeFETs. As shown in panel B, body bias line BuL₀ is coupled to transistors programmed to V_{TH1} (F₁, F₅, F₁₂), BuL₁ is coupled to transistors programmed to V_{TH2} (F₂, F₆, F₁₁), BuL₂ is coupled to transistors programmed to V_{TH3} (F₃, F₇, F₁₀), and BuL₃ is coupled to transistors programmed to V_{TH4} (F₄, F₈, F₉). The body bias lines are configured to selectively inhibit threshold voltage reprogramming of non-targeted transistors during write operations.

The scalability of the disclosed architecture is apparent from comparing the 4:1 multiplexer of FIG. 4 with the 8:1 multiplexer of FIG. 5. As the number of inputs and the number of available threshold voltage levels increase, the transistor savings and stage savings grow correspondingly. For a 16:1 multiplexer implemented with four threshold voltage levels, for example, the disclosed architecture uses twenty-four transistors in two stages, compared to thirty transistors in four stages for a conventional design (a 20% reduction in transistors and a reduction from four stages to two).

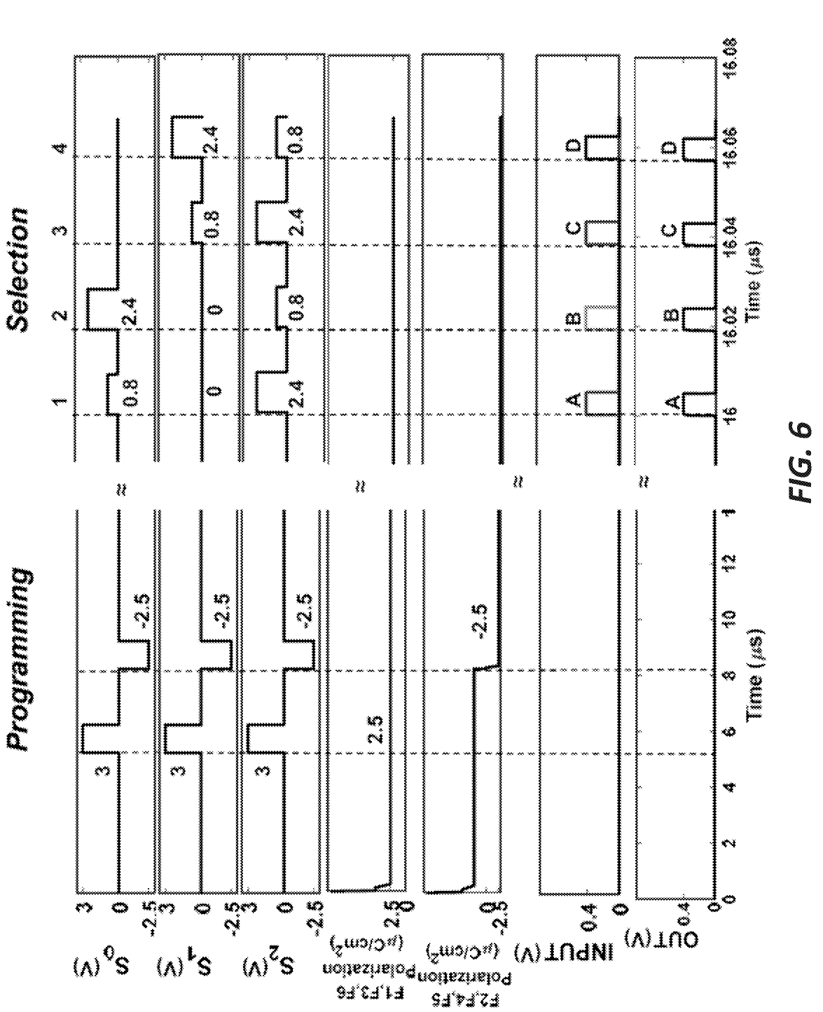

Referring now to FIG. 6, a timing diagram illustrates the transient response of the 4:1 multiplexer of FIG. 4, including a programming phase 602 and a selection phase 604. The timing diagram shows waveforms for select line voltages (S₀, S₁, S₂), input signals (A through D), and the multiplexer output.

In the programming phase 602, the FeFETs F₁ through F₆ are programmed to their respective threshold voltage states using a two-step write approach. In the first step, a positive write voltage of 3V is applied to all select lines (S₀, S₁, S₂) while all input terminals (A through D) and body bias lines (BuL₀, BuL₁) are grounded. This sets all FeFETs to a polarization state of approximately 2.5 µC/cm², corresponding to V_{TH1} (the lowest threshold voltage state). The V_{TH1} threshold voltage is approximately 0.4V.

In the second step, targeted FeFETs (F₂, F₄, F₅) are selectively reset to V_{TH2}. A write pulse of -2.5V is applied to all select lines (S₀, S₁, S₂). The body bias line BuL₀, which is coupled to the transistors that are to remain at V_{TH1} (F₁, F₃, F₆), is set to a voltage of -1.375V, which is more than half the write voltage. This inhibit bias voltage prevents the polarization of the non-targeted transistors from being disturbed. The body bias line BuL₁, which is coupled to the targeted transistors, is grounded, allowing those transistors to be reset to a polarization state of approximately -2.5 µC/cm², corresponding to V_{TH2}. The V_{TH2} threshold voltage is approximately 2.0V. After programming, the FeFETs retain their respective threshold voltage states nonvolatily.

In the selection phase 604, the multiplexer functionality is verified by selecting each input in turn. In each selection cycle, one input is held at logic 1 (400 mV) while all other inputs are held at logic 0 (GND). The select lines are biased with appropriate read voltages to activate the unique conduction path for the selected input, as described with reference to FIG. 4. To select input A, select lines are biased as (S₀, S₁, S₂) = (0.8V, 0V, 2.4V). The read voltage of 0.8V on S₀ corresponds to V_{R1} and turns on transistor F₁ (V_{TH1} ≈ 0.4V) while keeping F₂ (V_{TH2} ≈ 2.0V) off. The read voltage of 2.4V on S₂ corresponds to V_{R2} and turns on F₅ (V_{TH2}) and F₆ (V_{TH1}) in Block 01. Input A passes through transistors F₁ and F₅ to the output. To select input B, input C, and input D, the select line biasing is (2.4V, 0V, 0.8V), (0V, 0.8V, 2.4V), and (0V, 2.4V, 0.8V), respectively. The output waveform confirms that each selection cycle transfers the selected input signal to the output while all other inputs are blocked.

The read voltage magnitudes and read pulse durations may be selected such that the output receives more than 98% of the input voltage and such that the read pulses do not upset the programmed polarization states of the FeFETs. In some embodiments, the read pulse duration is limited to a few nanoseconds or less to avoid reprogramming the threshold voltages during multiplexer operation.

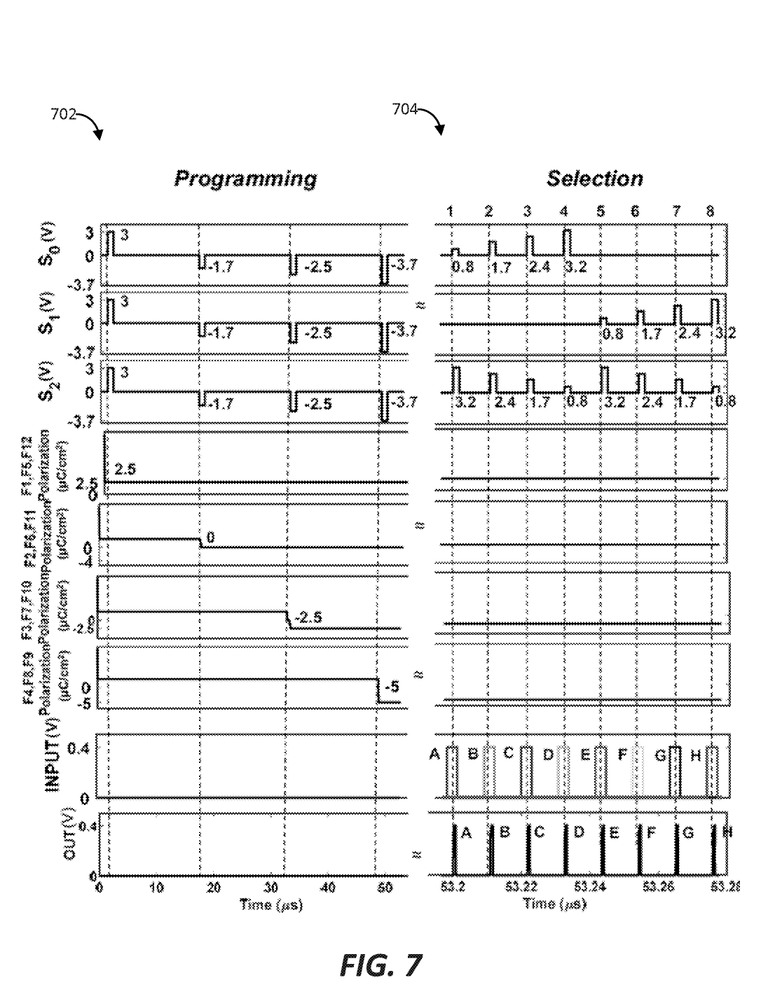

Referring now to FIG. 7, a timing diagram illustrates the transient response of the 8:1 multiplexer of FIG. 5 (panel B), including a programming phase 702 and a selection phase 704. The timing diagram shows waveforms for select line voltages (S₀, S₁, S₂), input signals (A through H), and the multiplexer output.

In the programming phase 702, the FeFETs F₁ through F₁₂ are programmed to their respective threshold voltage states using a multi-step write approach. In the first step, a positive write voltage of 3V is applied to all select lines (S₀, S₁, S₂) while all inputs (A through H) and all body bias lines (BuL₀ through BuL₃) are grounded. This sets all FeFETs to a polarization state of approximately 2.5 µC/cm², corresponding to V_{TH1} (the lowest threshold voltage state). The V_{TH1} threshold voltage is approximately 0.4V.

In the second step, target transistors F₂, F₆, and F₁₁ are selectively reset to V_{TH2}. A write pulse of -1.7V is applied to select lines S₀, S₁, and S₂. The body bias lines of non-targeted transistors are set to an inhibit bias voltage of approximately -2.22V (approximately 60% of the magnitude of the most negative write voltage used in the programming sequence, -3.7V) to prevent polarization upset. The body bias lines of the targeted transistors (F₂, F₆, F₁₁) are grounded, allowing those transistors to be reset to a polarization state of approximately 0 µC/cm², corresponding to V_{TH2}. The V_{TH2} threshold voltage is approximately 1.2V.

In the third step, target transistors F₃, F₇, and F₁₀ are selectively reset to V_{TH3}. A write pulse of -2.5V is applied to select lines S₀, S₁, and S₂. The body bias lines of non-targeted transistors remain at the inhibit bias voltage, while the body bias lines of the targeted transistors (F₃, F₇, F₁₀) are grounded. The targeted transistors are reset to a polarization state of approximately -2.5 µC/cm², corresponding to V_{TH3}. The V_{TH3} threshold voltage is approximately 2.0V.

In the fourth step, target transistors F₄, F₈, and F₉ are selectively reset to V_{TH4}. A write pulse of -3.7V is applied to select lines S₀, S₁, and S₂. The body bias lines of non-targeted transistors remain at the inhibit bias voltage, while the body bias lines of the targeted transistors (F₄, F₈, F₉) are grounded. The targeted transistors are reset to a polarization state of approximately -5 µC/cm², corresponding to V_{TH4}. The V_{TH4} threshold voltage is approximately 2.75V.

After the multi-step programming sequence, the twelve FeFETs hold four threshold voltage states: V_{TH1} ≈ 0.4V (F₁, F₅, F₁₂), V_{TH2} ≈ 1.2V (F₂, F₆, F₁₁), V_{TH3} ≈ 2.0V (F₃, F₇, F₁₀), and V_{TH4} ≈ 2.75V (F₄, F₈, F₉). These states are retained nonvolatily.

In the selection phase 704, the multiplexer functionality is verified by selecting each of the eight inputs in turn. In each selection cycle, one input is held at logic 1 while all other inputs are held at logic 0. Three different read voltages are applied to the select lines to select each input uniquely. Each read pulse has a duration sufficient to turn on the targeted FeFETs but short enough to avoid upsetting the programmed polarization states, which in this example is approximately 1.8 ns.

To select input A, the select lines are biased as (S₀, S₁, S₂) = (V_{R1}, 0, V_{R4}), corresponding to (0.8V, 0V, 3.2V). The voltage V_{R1} on S₀ turns on only F₁ (V_{TH1}) in Block 00. The voltage V_{R4} on S₂ turns on all transistors in Block 01. Input A passes through F₁ and F₉ to the output. To select input B, the biasing is (V_{R2}, 0, V_{R3}), corresponding to (1.7V, 0V, 2.4V). To select input C, the biasing is (V_{R3}, 0, V_{R2}), corresponding to (2.4V, 0V, 1.7V). To select input D, the biasing is (V_{R4}, 0, V_{R1}), corresponding to (3.2V, 0V, 0.8V).

To select inputs E through H, the first select line S₀ is set to 0V (deactivating Block 00) and the select line S₁ is activated. To select input E, the biasing is (0, V_{R1}, V_{R4}), corresponding to (0V, 0.8V, 3.2V). To select input F, the biasing is (0, V_{R2}, V_{R3}), corresponding to (0V, 1.7V, 2.4V). To select input G, the biasing is (0, V_{R3}, V_{R2}), corresponding to (0V, 2.4V, 1.7V). To select input H, the biasing is (0, V_{R4}, V_{R1}), corresponding to (0V, 3.2V, 0.8V).

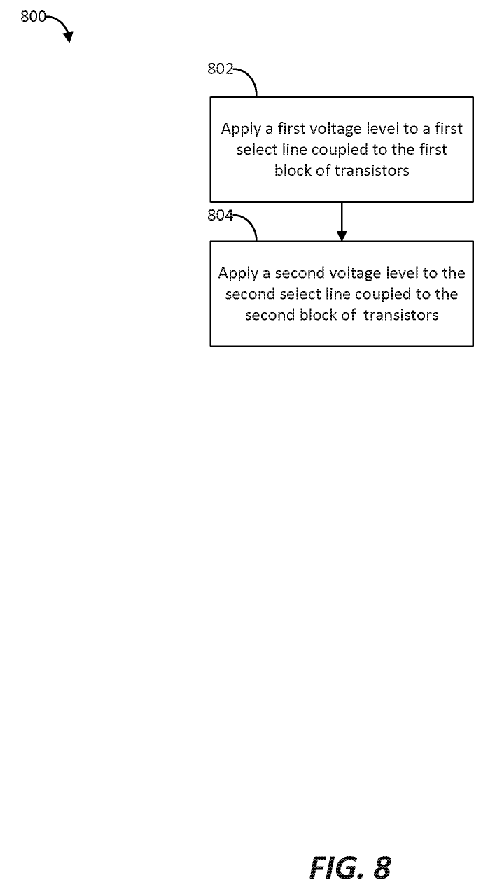

Referring now to FIG. 8, a flowchart illustrates a process 800 for operating a multiplexer having a first block and a second block (e.g., block 00 and block 01 of FIG. 3), each block comprising a plurality of variable-threshold transistors having different threshold voltages.

At operation 802, a first voltage level is applied to a first select line coupled to the first block (e.g., select line S00 and block 00). The first voltage level exceeds the threshold voltages of a first subset of the transistors in the first block and falls below the threshold voltages of a remaining subset of the transistors in the first block. The first voltage level is one of N discrete read voltages, where each discrete read voltage is greater than a respective one of N distinct threshold voltages and less than a next-higher one of the N distinct threshold voltages. By selecting the first voltage level from among the N discrete read voltages, a controlled number of transistors in the first block are turned on. For example, as described with reference to FIG. 3, applying a read voltage V_{R2} to the first select line turns on transistors having threshold voltages V_{TH1} and V_{TH2} while keeping transistors having threshold voltages V_{TH3} and V_{TH4} off.

At operation 804, a second voltage level is applied to a second select line coupled to the second block (e.g., select line S01 and block 01). The second voltage level activates a second subset of the transistors in the second block. The second voltage level is also selected from the N discrete read voltages. The combination of the first voltage level and the second voltage level is selected such that, together, they activate exactly one input-to-output path through the multiplexer.

The first voltage level and the second voltage level together conduct a selected input signal to an output of the multiplexer through a single input-to-output path spanning the first and second blocks. The selected input signal passes through one transistor of the first block and one transistor of the second block in series to reach the output terminal.

In some embodiments, the transistors in the first block are arranged in an ascending order of threshold voltage, and the transistors in the second block are arranged in a descending order of threshold voltage, or vice versa. This opposing arrangement provides that a signal passing through a high-threshold transistor in the first block passes through a low-threshold transistor in the second block, and vice versa, providing unique path selection for each combination of read voltages applied to the first and second select lines.

In some embodiments, each of the first block and the second block comprises N transistors having N distinct threshold voltages, and the first voltage level and the second voltage level are each selected from N discrete read voltages satisfying the interleaving relationship described with reference to FIG. 3.

In some embodiments, each of the first voltage level and the second voltage level is applied as a read pulse having a duration selected to avoid reprogramming the threshold voltages of the variable-threshold transistors. For example, as described with reference to FIG. 7, a read pulse duration may be limited to approximately 1.8 ns.

The method of FIG. 8 may be performed by multiplexer control circuitry that generates the appropriate multi-level voltage signals on the select lines. In some embodiments, the control circuitry includes voltage level shifters or digital-to-analog converters that produce the N discrete read voltage levels from digital selection inputs.

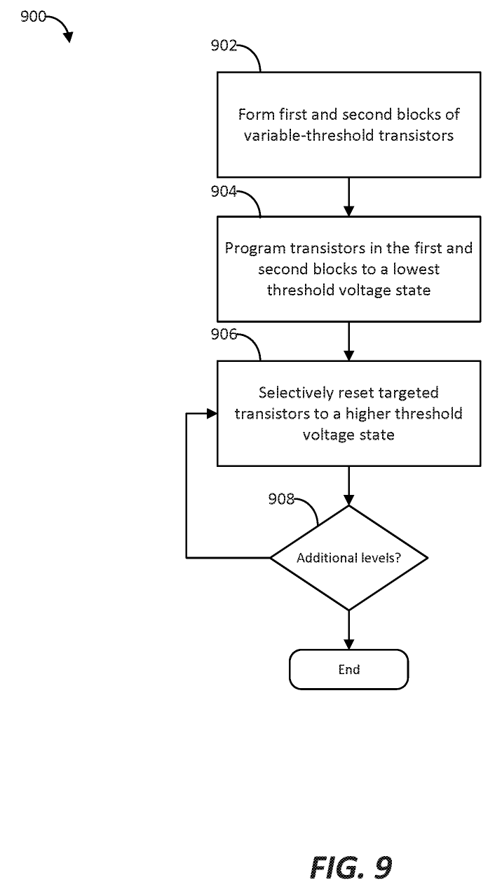

Referring now to FIG. 9, a flowchart illustrates a process 900 for manufacturing a multiplexer. The method of FIG. 9 is applicable to embodiments in which the variable-threshold transistors are FeFETs, though analogous programming or fabrication sequences may be used for other variable-threshold transistor technologies.

At operation 902, first and second blocks of transistors are fabricated with defined interconnections. In FeFET-based embodiments, each transistor is fabricated with the device structure described with reference to FIG. 1A, including the gate 102, the ferroelectric layer 104, the dielectric 106, the p-type substrate 108, and/or the n+ source and drain regions 110, 112. The transistors in the first block are coupled to respective input terminals and to a first select line. The transistors in the second block are coupled to a second select line, and each transistor in the second block is connected in series with a respective transistor in the first block to form a plurality of input-to-output paths.

The physical layout defines which input terminal connects to which transistor position in the first block and which first-block transistor position maps to which second-block transistor position in series. In some embodiments, additional blocks are formed in the first stage (e.g., block 10 as described with reference to FIGS. 4 and 5) to increase the number of multiplexer inputs. The physical arrangement of the transistors and their interconnections may be defined during integrated circuit fabrication, for example as part of an FPGA or ASIC layout.

For FeFET-based embodiments, the threshold voltage ordering is imposed electrically in operations 904 through 908, described below. For embodiments using conventional NMOS transistors with fixed threshold voltages, the threshold voltage of each transistor may instead be set during fabrication through different channel doping concentrations, gate oxide thicknesses, and/or gate work functions at each transistor site.

At operation 904, the transistors in the first and second blocks are programmed to a lowest threshold voltage state by applying a positive write voltage to the select lines while grounding all input terminals and body bias lines. As described with reference to FIG. 6, for example, a write voltage of 3V applied for approximately 1 µs sets all FeFETs to a polarization state of approximately 2.5 µC/cm², corresponding to V_{TH1}.

At operation 906, targeted transistors are selectively reset to a higher threshold voltage state. A negative write voltage is applied to the select lines while an inhibit bias voltage is applied to the body bias lines of non-targeted transistors. The body bias lines of the targeted transistors are grounded, allowing only the targeted transistors to be reprogrammed. The inhibit bias voltage is set to a magnitude sufficient to prevent polarization upset of the non-targeted transistors. In some embodiments, the inhibit bias voltage is between 50% and 60% of the magnitude of the negative write voltage. For example, as described with reference to FIG. 6, for the 4:1 multiplexer, an inhibit bias voltage of -1.375V (approximately 55% of the -2.5V write voltage) is used; as described with reference to FIG. 7, for the 8:1 multiplexer, an inhibit bias voltage of -2.22V (approximately 60% of the -3.7V write voltage) is used.

At operation 908, the selective reset of operation 906 is repeated for additional threshold voltage levels as needed. For a multiplexer with two threshold voltage levels (e.g., the 4:1 multiplexer of FIG. 4), only one selective reset step is performed at operation 906, resetting targeted transistors from V_{TH1} to V_{TH2}. For a multiplexer with four threshold voltage levels (e.g., the 8:1 multiplexer of FIG. 5), three selective reset steps are performed sequentially: a first reset to V_{TH2} using a write voltage of -1.7V, a second reset to V_{TH3} using a write voltage of -2.5V, and a third reset to V_{TH4} using a write voltage of -3.7V. Each successive reset step targets a different group of transistors while maintaining the inhibit bias on all non-targeted transistors. The loop from operation 908 back to operation 906 is repeated until all N distinct threshold voltage levels have been programmed across the transistors in the multiplexer.

After the programming sequence of FIG. 9 is complete, the threshold voltage states are retained nonvolatily in the ferroelectric layer of each FeFET, and the multiplexer is ready for operation according to the method of FIG. 8.

In some embodiments, one or more steps of the methods of FIGS. 8 and 9 may be performed or controlled by a computing device, for example to generate the multi-level voltage signals on the select lines or to execute the programming sequence.

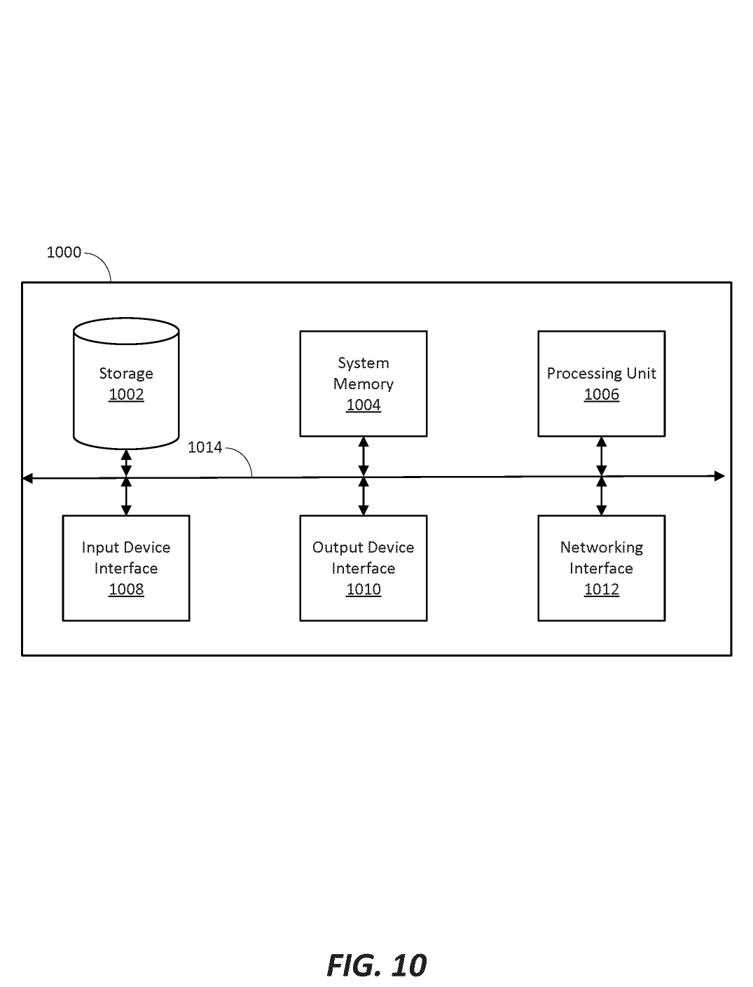

FIG. 10 is a block diagram of an example electronic device 1000 with which aspects of the present disclosure may be implemented. The electronic device 1000 may be, and/or may be part of, any electronic device for generating the features and processes described in reference to the foregoing figures, including but not limited to a desktop computer, server computer, tablet computer, smartphone, and wearable device (e.g., smartwatch, fitness band). The electronic device 1000 may include various types of computer-readable media and interfaces for various other types of computer-readable media. The electronic device 1000 includes a processing unit 1006, persistent storage device 1002, system memory 1004, input device interface 1008, output device interface 1010, bus 1014, and/or network interface 1012.

The bus 1014 collectively represents all system, peripheral, and chipset buses that communicatively connect the numerous internal components of the electronic device 1000. In one or more embodiments, the bus 1014 communicatively couples the processing unit 1006 with the system memory 1004 and/or the persistent storage device 1002. From these various memory units, the processing unit 1006 retrieves instructions to execute and data to process in order to execute the processes of the subject disclosure. The processing unit 1006 can be one or more processors, each of which can be a single- or multi-core processor.

The persistent storage device 1002 may be a non-volatile memory unit that stores instructions and data. The persistent storage device 1002 may be or include a mass-storage device (e.g., a magnetic or optical disk and its corresponding disk drive). In some embodiments, a removable storage device (e.g., a floppy disk, flash drive, and its corresponding disk drive) may be used as the persistent storage device 1002.

The system memory 1004 may be a volatile read-and-write memory, such as RAM. The system memory 1004 may store any of the instructions and data that the processing unit 1006 may need at runtime. In some embodiments, the processes of the present disclosure are stored in the system memory 1004 and/or the persistent storage device 1002. From these various memory units, the processing unit 1006 retrieves instructions to execute and data to process in order to execute the processes of one or more implementations.

The bus 1014 also connects to the input device interface 1008 and output device interface 1010. The input device interface 1008 enables a user to communicate information and send commands to the electronic device 1000. Input devices that may be used with the input device interface 1008 may include, for example, keyboards, touch screens, and pointing devices. The output device interface 1010 may enable, for example, the display of text and/or images generated by electronic device 1000. Output devices that may be used with the output device interface 1010 may include, for example, printers and display devices, such as a liquid crystal display (LCD), a light emitting diode (LED) display, an organic light emitting diode (OLED) display, a flexible display, a flat panel display, a projector, or any other device for outputting information.

One or more embodiments may include devices that function as both input and output devices, such as a touchscreen. Feedback provided to the user can be any form of sensory feedback, such as visual feedback, auditory feedback, or tactile feedback. Input from the user may be received in any form, including acoustic, speech, or tactile input.

The bus 1014 also couples the electronic device 1000 to one or more networks and/or to one or more network nodes through the network interface 1012. In this manner, the electronic device 1000 can be a part of a network of computers (such as a local area network (LAN), a wide area network (WAN), or an intranet, or a network of networks, such as the internet). Any or all components of the electronic device 1000 can be used in conjunction with the present disclosure.

Implementations within the scope of the present disclosure can be partially or entirely realized using a tangible computer-readable storage medium (or multiple tangible computer-readable storage media of one or more types) encoding one or more instructions. The tangible computer-readable storage medium also can be a non-transitory computer-readable medium.

The computer-readable storage medium can be any storage medium that can be read, written, or otherwise accessed by a general purpose or special purpose computing device, including any processing electronics and/or processing circuitry capable of executing instructions. For example, without limitation, the computer-readable medium can include any volatile semiconductor memory, such as RAM, DRAM, SRAM, T-RAM, Z-RAM, and TTRAM. The computer-readable medium also can include any non-volatile semiconductor memory, such as ROM, PROM, EPROM, EEPROM, NVRAM, and flash.

Further, the computer-readable storage medium can include any non-semiconductor memory, such as optical disk storage, magnetic disk storage, magnetic tape, other magnetic storage devices, or any other medium capable of storing machine-readable instructions. In one or more implementations, the tangible computer-readable storage medium can be directly coupled to a computing device, while in other implementations, the tangible computer-readable storage medium can be indirectly coupled to a computing device, e.g., via one or more wired and/or wireless connections.

Instructions can be directly executable or can be used to develop executable instructions. For example, instructions can be realized as executable or non-executable machine code or as instructions in a high-level language that can be compiled to produce executable or non-executable machine code. Further, instructions also can be realized as or can include data. Computer-executable instructions also can be organized in any format, including routines, subroutines, programs, data structures, objects, modules, applications, applets, functions, etc. As recognized by those of skill in the art, details including, but not limited to, the number, structure, sequence, and organization of instructions can vary significantly without varying the underlying logic, function, processing, and output.

While the above discussion primarily refers to microprocessor or multi-core processors that execute software, one or more implementations are performed by one or more integrated circuits, such as ASICs or FPGAs. In one or more implementations, such integrated circuits execute instructions that are stored on the circuit itself.

While the examples provided herein illustrate specific implementations and applications, it is understood that the disclosed subject matter encompasses a wide range of configurations, adaptations, and use cases within the scope of the claims.

Those of skill in the art would appreciate that the various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled persons may implement the described functionality in varying ways for each particular application. Various components and blocks may be arranged differently (e.g., arranged in a different order, or partitioned in a different way) all without departing from the scope of the present disclosure.

While this disclosure has described certain embodiments, it is understood that the claims are not intended to be limited to these embodiments except as explicitly recited in the claims. On the contrary, the instant disclosure is intended to cover alternatives, modifications, and equivalents, which may be included within the spirit and scope of the disclosure. Furthermore, in the detailed description of the present disclosure, numerous specific details are set forth in order to provide a thorough understanding of the disclosed embodiments. However, the present disclosure is not limited to the specific details set forth herein and can be practiced using one or more other embodiments. In other instances, well known methods, procedures, components, and circuits have not been described in detail as not to unnecessarily obscure various aspects of the present disclosure. Additionally, in one or more embodiments, structures and components are shown in block diagram form to avoid obscuring the concepts of the present disclosure.

Some portions of the detailed descriptions of this disclosure have been presented in terms of procedures, logic blocks, processing, and other symbolic representations of operations on data bits within a computer or digital system memory. These descriptions and representations are the means used by those skilled in the data processing arts to most effectively convey the substance of their work to others skilled in the art. A procedure, logic block, process, etc., is herein, and generally, conceived to be a self-consistent sequence of steps or instructions leading to a desired result. The steps are those requiring physical manipulations of physical quantities. Usually, though not necessarily, these physical manipulations take the form of electrical or magnetic data capable of being stored, transferred, combined, compared, and otherwise manipulated in a computer system or similar electronic computing device. For reasons of convenience, and with reference to common usage, such data is referred to as bits, values, elements, symbols, characters, terms, numbers, or the like, with reference to various presently disclosed embodiments. It is understood, however, that these terms are to be interpreted as referencing physical manipulations and quantities and are merely convenient labels that should be interpreted further in view of terms commonly used in the art.

Unless specifically stated otherwise, as apparent from the discussion herein, it is understood that throughout discussions of the present embodiment, discussions utilizing terms such as “determining” or “outputting” or “transmitting” or “recording” or “locating” or “storing” or “displaying” or “receiving” or “recognizing” or “utilizing” or “generating” or “providing” or “accessing” or “checking” or “notifying” or “delivering” or the like, refer to the action and processes of a computer system, or similar electronic computing device, that manipulates and transforms data. The data is represented as physical (electronic) quantities within the computer system’s registers and memories and is transformed into other data similarly represented as physical quantities within the computer system memories or registers, or other such information storage, transmission, or display devices as described herein or otherwise understood to one of ordinary skill in the art.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Any of the blocks may be performed simultaneously. In one or more implementations, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refers to only A, only B, or only C; any combination of A, B, and C; and/or at least one of any of A, B, and C.

Phrases such as an aspect, the aspect, another aspect, some aspects, one or more aspects, an implementation, the implementation, another implementation, one or more implementations, one or more implementations, an embodiment, the embodiment, another embodiment, one or more implementations, one or more implementations, a configuration, the configuration, another configuration, some configurations, one or more configurations, the subject technology, the disclosure, the present disclosure, other variations thereof and alike are for convenience and do not imply that a disclosure relating to such phrase(s) is essential to the present disclosure or that such disclosure applies to all configurations of the present disclosure. A disclosure relating to such phrase(s) may apply to all configurations or one or more configurations. A disclosure relating to such phrase(s) may provide one or more examples. A phrase such as an aspect or some aspects may refer to one or more aspects and vice versa, and this applies similarly to other foregoing phrases.

Any implementation described herein as “exemplary” or as an “example” is not necessarily to be construed as preferred or advantageous over other implementations. Furthermore, to the extent that the term “include,” “have,” or the like is used in the description or the claims, such term is intended to be inclusive in a manner similar to the term “comprise” as “comprise” is interpreted when employed as a transitional word in a claim.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language claims, wherein reference to an element in the singular is not intended to mean “one and only one” unless specifically so stated, but rather “one or more.” Unless specifically stated otherwise, the term “some” refers to one or more. Headings and subheadings, if any, are used for convenience only and do not limit the subject disclosure.

What is claimed is:

1. A multiplexer circuit, comprising:
a first block of variable-threshold transistors coupled to a first select line, the transistors in the first block arranged in an ascending order of threshold voltage; and
a second block of variable-threshold transistors coupled to a second select line, the transistors in the second block arranged in a descending order of threshold voltage, each transistor in the second block connected in series with a respective transistor in the first block to form a plurality of input-to-output paths,
wherein applying a respective voltage level to each of the first and second select lines activates a single input-to-output path through the first and second blocks.

2. The multiplexer circuit of claim 1, wherein each of the variable-threshold transistors comprises a ferroelectric field-effect transistor (FeFET).

3. The multiplexer circuit of claim 2, wherein each FeFET comprises a ferroelectric hafnium oxide layer in a gate stack.

4. The multiplexer circuit of claim 1, wherein each block comprises N variable-threshold transistors having N distinct threshold voltages, and wherein the plurality of input-to-output paths comprises N input-to-output paths.

5. The multiplexer circuit of claim 4, wherein N is two, and the multiplexer circuit implements a 4:1 multiplexer.

6. The multiplexer circuit of claim 4, wherein N is four, and the multiplexer circuit implements an 8:1 multiplexer.

7. The multiplexer circuit of claim 4, wherein each of the respective voltage levels applied to the first and second select lines is one of N discrete read voltages, each of the N discrete read voltages exceeds a respective one of the N distinct threshold voltages, each of the N distinct threshold voltages other than a lowest threshold voltage exceeds the discrete read voltage associated with a next-lower threshold voltage, and a highest discrete read voltage of the N discrete read voltages exceeds a highest threshold voltage of the N distinct threshold voltages.

8. The multiplexer circuit of claim 1, further comprising:
a third select line; and
a third block of variable-threshold transistors coupled to the third select line, the transistors in the third block arranged in an ascending order of threshold voltage and coupled to respective additional input terminals,
wherein the second block receives intermediate outputs from the first block and the third block.

9. The multiplexer circuit of claim 1, further comprising a plurality of body bias lines, each body bias line coupled to a respective group of the variable-threshold transistors sharing a common programmed threshold voltage state, the body bias lines configured to selectively inhibit threshold voltage reprogramming of non-targeted transistors during a write operation.

10. The multiplexer circuit of claim 1, wherein the variable-threshold transistors are pass transistors, and wherein each input-to-output path couples a respective input terminal to an output terminal through one transistor of the first block and one transistor of the second block.

11. The multiplexer circuit of claim 1, wherein the multiplexer circuit is incorporated in a field-programmable gate array (FPGA).

12. The multiplexer circuit of claim 1, wherein the multiplexer circuit is incorporated in an application-specific integrated circuit (ASIC).

13. A method of operating a multiplexer including a first block and a second block, each block comprising a plurality of variable-threshold transistors having different threshold voltages, the method comprising:
applying a first voltage level to a first select line coupled to the first block, the first voltage level exceeding the threshold voltages of a first subset of the transistors in the first block and falling below the threshold voltages of a remaining subset of the transistors in the first block; and
applying a second voltage level to a second select line coupled to the second block, the second voltage level activating a second subset of the transistors in the second block,
wherein the first voltage level and the second voltage level together conduct a selected input signal to an output of the multiplexer through a single input-to-output path spanning the first and second blocks.

14. The method of claim 13, wherein the variable-threshold transistors comprise ferroelectric field-effect transistors (FeFETs), the method further comprising, before applying the first voltage level:
programming the transistors in the first block and the second block to their respective threshold voltages by applying a write voltage to the first and second select lines to set the transistors to a lowest threshold voltage state; and
selectively resetting targeted transistors to higher threshold voltage states by applying a negative write voltage to the first and second select lines while applying an inhibit bias voltage to body bias lines of non-targeted transistors.

15. The method of claim 14, wherein the inhibit bias voltage is between 50% and 60% of a magnitude of the negative write voltage.

16. The method of claim 13, wherein the transistors in the first block are arranged in an ascending order of threshold voltage, and the transistors in the second block are arranged in a descending order of threshold voltage.

17. The method of claim 13, wherein each of the first block and the second block comprises N transistors having N distinct threshold voltages, and wherein the first voltage level and the second voltage level are each selected from N discrete read voltages, each of the N discrete read voltages exceeds a respective one of the N distinct threshold voltages, wherein each of the N distinct threshold voltages other than a lowest threshold voltage exceeds the discrete read voltage associated with a next-lower threshold voltage, and a highest discrete read voltage of the N discrete read voltages exceeds a highest threshold voltage of the N distinct threshold voltages.

18. The method of claim 13, further comprising:
applying a third voltage level to a third select line coupled to a third block of the multiplexer, the third voltage level activating a third subset of the transistors in the third block,
wherein the first voltage level, the second voltage level, and the third voltage level together conduct a selected input signal to an output of the multiplexer through a single input-to-output path.

19. The method of claim 13, wherein each of the first voltage level and the second voltage level is applied as a read pulse having a duration selected to avoid reprogramming the threshold voltages of the variable-threshold transistors.

20. A pass transistor multiplexer, comprising:
a first block of pass transistors coupled between respective input terminals and a set of intermediate nodes, the first block coupled to a first select line, the pass transistors of the first block having N distinct threshold voltages arranged in ascending order; and
a second block of pass transistors coupled between the set of intermediate nodes and an output terminal, the second block coupled to a second select line, the pass transistors of the second block having the N distinct threshold voltages arranged in descending order corresponding to the intermediate nodes,
wherein each of N discrete read voltages exceeds a respective one of the N distinct threshold voltages, wherein each of the N distinct threshold voltages other than a lowest threshold voltage exceeds the discrete read voltage associated with a next-lower threshold voltage, a highest discrete read voltage of the N discrete read voltages exceeds a highest threshold voltage of the N distinct threshold voltages, and applying a first read voltage of the N discrete read voltages to the first select line and a second read voltage of the N discrete read voltages to the second select line activates exactly one input-to-output path from a respective input terminal to the output terminal.
